(19) United States
(12) Patent Application Publication
(10) Pub. No.: US 2026/0068682 A1
(43) Pub. Date: Mar. 5, 2026

(54) TRANSMITTING ELECTROMAGNETIC SIGNALS BETWEEN INTEGRATED CIRCUIT DEVICES AND SIGNAL CARRYING STRUCTURES

(71) Applicant: Ciena Corporation, Hanover, MD (US)

(72) Inventors: Lam Nguyen, Quebec (CA); Gregory Brookes, Quebec (CA); Etienne Therriault, Quebec (CA); Charbel Matta, Quebec (CA); Amir Askarian, Quebec (CA)

(73) Assignee: Ciena Corporation, Hanover, MD (US)

(21) Appl. No.: 18/816,721

(22) Filed: Aug. 27, 2024

(51) Int. Cl. H01L 23/66

(52) U.S. Cl. CPC H01L 23/66

(57) ABSTRACT

In one aspect, in general, an apparatus for transmitting signals between an integrated circuit device and a signal carrying structure comprises: a first interface comprising a plurality of device coupling transmission lines (DCTLs) distributed along a first axis contained within a first plane, each DCTL comprising at least two conductor strips distributed along the first axis and substantially coplanar with the first plane; a second interface comprising a plurality of signal carrying structure coupling transmission lines (SCSCTLs) distributed along a second axis, wherein each SCSCTL comprises at least two conductor strips distributed along a respective axis that is substantially perpendicular to the second axis; and a transition region between the first interface and the second interface comprising a transition structure comprising different respective conductors connecting each conductor strip of a DCTL to a respective conductor strip of a corresponding SCSCTL.

### TECHNICAL FIELD

This disclosure relates to transmitting electromagnetic signals between integrated circuit devices and signal carrying structures.

### BACKGROUND

As electrical, opto-electrical (OE) and electro-optic (EO) devices increase in complexity and performance, so does the demand for smaller device footprints driven by co-packaging. A strategy for reducing device footprints and packaging sizes to stay within industry needs of increased performance and decreased power consumption can involve optimizing device design by bringing integrated circuit (IC) components as close together as possible.

### SUMMARY

In one aspect, in general, an apparatus for transmitting electromagnetic signals between an integrated circuit device and a signal carrying structure comprises: a first interface configured to couple to the integrated circuit device, the first interface comprising a plurality of device coupling transmission lines (DCTLs) distributed along a first axis contained within a first plane, each DCTL comprising at least two conductor strips that are distributed along the first axis and are substantially coplanar with the first plane; a second interface configured to couple to the signal carrying structure, the second interface comprising a plurality of signal carrying structure coupling transmission lines (SCSCTLs) distributed along a second axis, wherein each SCSCTL comprises at least two conductor strips that are distributed along a respective axis that is substantially perpendicular to the second axis; and a transition region between the first interface and the second interface, the transition region comprising a transition structure comprising different respective conductors connecting each conductor strip of a DCTL to a respective conductor strip of a corresponding SCSCTL.

Aspects can include one or more of the following features.

The conductor strips of each SCSCTL are substantially parallel to a second plane that contains the second axis and that is perpendicular to the respective axis along which the conductor strips are distributed.

At least a portion of each of the conductor strips of a respective SCSCTL at least partially overlaps with a plane that is perpendicular to the second axis.

The second axis is substantially parallel to the first axis.

Each of the lengths of the two conductor strips in a DCTL are based at least in part on at least one of: (1) the transition structure, or (2) the respective conductor strips of the corresponding SCSCTL.

The first interface is configured to suppress signal crosstalk between adjacent DCTLs, and the second interface is configured to suppress crosstalk between adjacent SCSCTLs.

In another aspect, in general, an apparatus for transmitting electromagnetic signals between an integrated circuit device and a signal carrying structure comprises: a first interface configured to couple to the integrated circuit device, the first interface comprising at least one DCTL that comprises first and second conductor strips that are substantially coplanar with a first plane; a second interface configured to couple to the signal carrying structure, the second interface comprising at least one SCSCTL that comprises third and fourth conductor strips that are distributed along an axis that is substantially perpendicular to the first plane; and a transition region between the first interface and the second interface, the transition region comprising a first coupling location coplanar with the first plane, a second coupling location coplanar with the first plane and positioned closer to the second interface than the first coupling location, a first transition structure comprising a first conductor extending to a first distance from the first plane and connecting the first coupling location to the fourth conductor strip, and a second conductor extending to a second distance from the first plane and connecting the second coupling location to the third conductor strip, and a second transition structure comprising a third conductor coplanar with the first plane and connecting the second coupling location to the first conductor strip, and a fourth conductor coplanar with the first plane and connecting the first coupling location to the second conductor strip; wherein the third conductor and the fourth conductor are configured to at least partially compensate for a delay associated with electromagnetic signals propagating through one or more of: the first transition structure, the first conductor strip, the second conductor strip, the third conductor strip, or the fourth conductor strip.

Aspects can include one or more of the following features.

The first interface and the second transition structure comprise a first material having a first dielectric constant, and the second interface and the second transition structure comprise a second material having a second dielectric constant.

The first dielectric constant and the second dielectric constant are different and the third conductor and the fourth conductor are configured to at least partially compensate for a delay associated with electromagnetic signals propagating through the first material and the second material.

The delay compensation is based at least in part on (1) a length of the third conductor, and (2) a difference between a length of the first conductor and a length of the second conductor.

At least a portion of the first conductor extends along an axis that is perpendicular to the first plane.

The portion of the first conductor that extends along the axis has a length and a thickness that is based at least in part on the length.

At least a portion of the second conductor extends along an axis that is perpendicular to the first plane.

The transition structure includes a plurality of ground vias, each ground via in the plurality of ground vias extending along an axis that is perpendicular to the first plane.

The first coupling location and the second coupling location are distributed along an axis that contains the first conductor strip or the second conductor strip of the at least one DCTL.

The second interface is configured to suppress signal crosstalk between the third conductor strip and the fourth conductor strip in the SCSCTL.

The first transition structure comprises one or more layers of a material having a first dielectric constant, where each layer is substantially coplanar with a plane that is parallel to the first plane.

In another aspect, in general, an apparatus for carrying electromagnetic signals between an integrated circuit device and a signal carrying structure comprises: a first interface configured to couple to the integrated circuit device, the first interface comprising a plurality of edge-coupled coplanar striplines distributed along a first axis, where each edge-coupled coplanar stripline comprises at least two conductor strips; a second interface configured to couple to the signal carrying structure, the second interface comprising a plurality of broadside-coupled striplines distributed along a second axis, where each broadside-coupled stripline comprises at least two conductor strips; and a transition region between the first interface and the second interface, the transition region comprising a transition structure comprising different respective conductors connecting each conductor strip of an edge-coupled coplanar stripline to a respective conductor strip of a corresponding broadside-coupled stripline.

Aspects can include one or more of the following features.

The first axis is substantially parallel to the second axis.

The first interface is configured to suppress signal crosstalk between adjacent edge-coupled coplanar striplines, and the second interface is configured to suppress crosstalk between adjacent broadside-coupled coplanar striplines.

Aspects can have one or more of the following advantages.

The methods and systems described herein comprise a connector configured to transmit electromagnetic signals between an integrated circuit device comprising multiple transmission lines and a signal carrying structure comprising multiple transmission lines. Some connector configurations can facilitate the manufacture and production of devices with reduced physical footprints and greater device performance. The reduced footprint can allow for more space for other electro-optical components. Some connector configurations can also allow for electromagnetic conduction channels with reduced lengths, which can also reduce signal conduction losses such as mode conversion, intra-channel skew, and crosstalk.

Other features and advantages will become apparent from the following description, and from the figures and claims.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIGS. 1A-1C are schematic diagrams of an example connector structure for integrated circuit devices and signal carrying structures.

FIGS. 2A-2C are schematic diagrams of an example connector structure for integrated circuit devices and signal carrying structures.

FIGS. 3A-3F are schematic diagrams of an example device connected to a signal carrying structure.

FIGS. 4A-4F are schematic diagrams of an example device connected to a signal carrying structure.

FIGS. 5A-5B is schematic diagrams of an example connector structure for integrated circuit devices and signal carrying structures.

FIGS. 6A-6B are schematic diagrams of an example device comprising multiple connector structures.

FIGS. 7A-7C are schematic diagrams of an example device comprising a transition structure that includes ground vias.

### DETAILED DESCRIPTION

Some electrical, EO, or OE devices can comprise multiple components that include transmission lines configured to carry or transmit electromagnetic signals, such as radiofrequency (RF) signals. For example, components with transmission lines can include integrated circuit chips, electro-optical chips, and signal carrying structures. In some devices, RF transmission lines can be interconnected across multiple components. In these devices, matching the pitch and spacing of RF transmission lines between components can be a consideration in optimizing device performance and footprints. For instance, matching the interconnected pitch of RF transmission lines can reduce electrical loss while also reducing device packaging sizes to stay within industry standards.

Some transmission lines comprise two or more conductors over which electromagnetic signals are transmitted. Some transmission lines are configured to transmit signals using a single ended configuration, where one of the conductors transmits a signal while the other conductor is grounded. Some transmission lines can be configured to transmit an electromagnetic signal by transmitting a pair of differential electromagnetic signals. These differential transmission lines can comprise a pair of conductor strips wherein one conductor strip carries a signal that is antiphase with a signal carried by the other conductor strip. In some implementations, differential transmission lines also include one or more grounded conductor strips.

Some transmission lines can have an edge-coupled coplanar stripline (ECCPS) configuration comprising a pair of conductor strips that are arranged to be substantially coplanar with a plane. Some transmission lines can have a broadside-coupled stripline (BCS) configuration wherein one conductor strip in a pair of conductor strips is arranged along an axis that is perpendicular to a plane that is coplanar with the other conductor strip. In some implementations the conductor strips of a BCS transmission line are completely overlapping with each other when viewed along that axis, as in some of the examples illustrated and described herein. But, in other examples, the conductor strips are not necessarily completely overlapping, but may be at least partially overlapping.

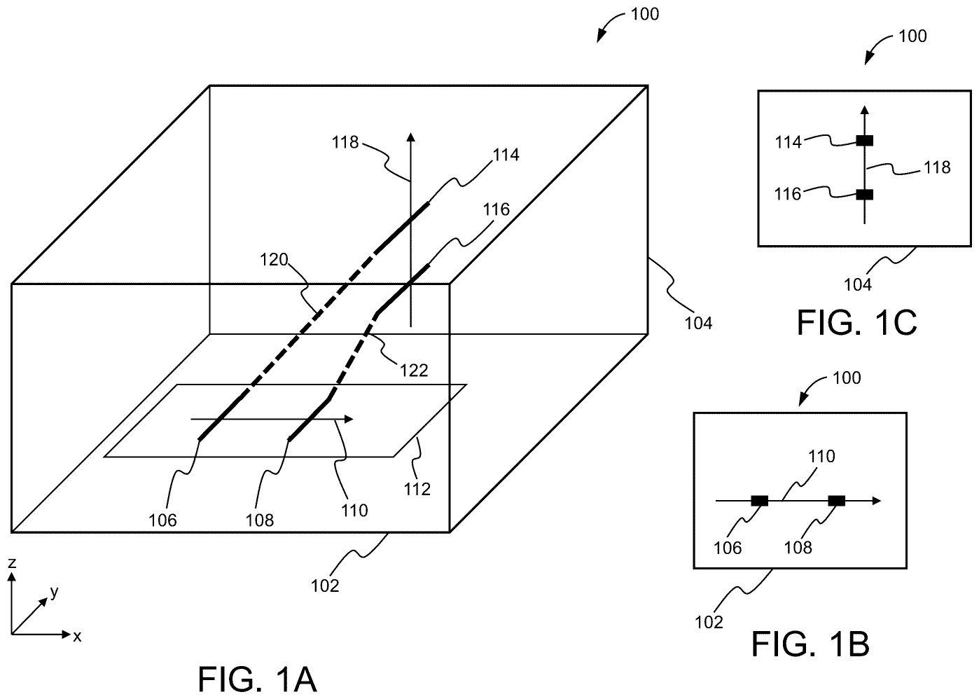

Some electrical, EO, or OE devices can comprise an integrated circuit device with an ECCPS transmission line that is connected to a BCS transmission line in a signal carrying structure. In such devices, a connector structure can be utilized to connect the conductor strips of the ECCPS transmission line to the conductor strips of the BCS transmission line. FIG. 1A depicts an isometric view of an example connector structure 100 with a first interface 102 configured to connect to an integrated circuit device and a second interface 104 configured to connect to a signal carrying structure. FIG. 1B depicts a front view of the example connector structure 100 and the first interface 102. The first interface 102 comprises a conductor strip 106 and a conductor strip 108 that are arranged along an axis 110. In this example, the axis 110 is parallel to the x-axis of a coordinate system shown in the lower left corner of FIG. 1A. The conductor strips 106 and 108 and the axis 110 are coplanar with a plane 112. FIG. 1C depicts a back view of the example connector structure 100 and the second interface 104. The second interface 104 comprises a conductor strip 114 and a conductor strip 116 that are arranged along an axis 118 that is perpendicular to the axis 110. In this example, the axis 118 is parallel to the z-axis of the coordinate system shown in the lower left corner of FIG. 1A. Between the first interface 102 and the second interface 104 is a transition region comprising a conductor 120 and a conductor 122. The conductor 120 connects the conductor strip 106 with the conductor strip 114 while the conductor 122 connects the conductor strip 108 with the conductor strip 116. In some example systems, the transition region can comprise a pair of conductors connecting conductor strip 106 with conductor strip 116 and conductor strip 108 with conductor strip 114.

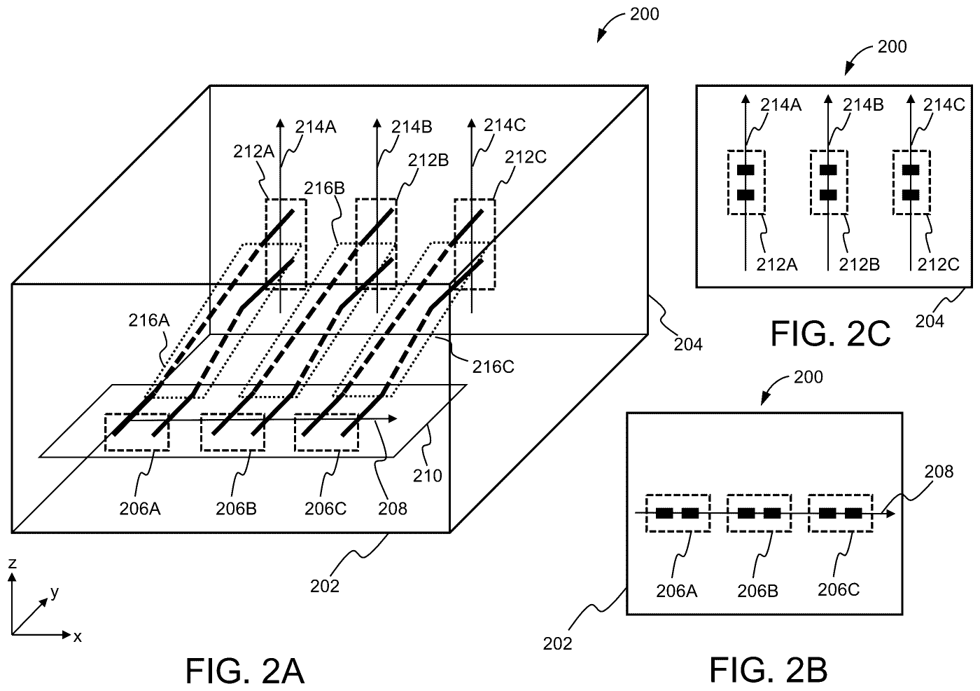

An electrical, EO, or OE device can comprise an integrated circuit device with a plurality of ECCPS transmission lines that are each connected to a respective one of a plurality of BCS transmission lines in a signal carrying structure by a connector structure. FIG. 2A depicts an isometric view of an example connector structure 200 with a first interface 202 configured to connect to an integrated circuit device and a second interface 204 configured to connect to a signal carrying structure. FIG. 2B depicts a front view of the example connector structure 200 and the first interface 202. The first interface 202 comprises a plurality of device coupling transmission lines (DCTLs) 206A, 206B, 206C that each comprise a pair of conductor strips. The DCTLs 206A, 206B, 206C are arranged along a first axis 208 and are coplanar with a plane 210. FIG. 2C depicts a back view of the example connector structure 200 and the second interface 204. The second interface 204 comprises a plurality of signal carrying structure coupling transmission lines (SCSCTLs) 212A, 212B, 212C that each comprise a pair of conductor strips that are arranged along axes 214A, 214B, 214C, respectively. The axes 214A, 214B, 214C are perpendicular to the first axis 208. Between the first interface 202 and the second interface 204 is a transition region comprising a plurality of transition structures 216A, 216B, 216C. Each transition structure 216A, 216B, 216C comprises different respective conductors connecting each conductor strip of a DCTL 206A, 206B, 206C to a respective conductor strip of a corresponding SCSCTL 212A, 212B, 212C.

In some connector structures, each DCTL can comprise at least two conductor strips that are distributed along the first axis 208 and are coplanar with the plane 210. In some connector structures, each signal carrying structure connector transmission line can comprise at least two conductor strips that are distributed along the axes 214A, 214B, 214C.

Without using some of the connector features described herein that enable compact connector configurations, a fanning connector configuration may comprise ECCPS transmission lines associated with an integrated circuit device that are coupled to ECCPS transmission lines associated with a signal carrying structure. In some fanning connector configurations, the conductor strips in the ECCPS transmission line of the intregrated circuit device have a different pitch than the conductor strips in the ECCPS transmission line of the signal carrying structure. In these fanning connector configurations, a “fan-in” portion of a connector including conductor strips with different pathlengths and bends can be utilized to connect the wider ECCPS transmission lines of the signal carrying structure (e.g., a cable) to the narrower ECCPS transmission lines of the device. This fanning connector configuration can be associated unwanted and adverse consequences including: (1) reduced useful area in package (2) increased conduction losses (3) increased skew (intra and inter-channel) (4) increased mode conversion (5) increased crosstalk. Such fanning connector configuration can occupy a considerable area in a device package, drastically limiting the space for other components. This size requirement can be a considerable limitation in implementing EO components such as a Mach-Zehnder modulator, as a component's performance can be proportional to the length of the component. Longer lines due to this fan-in can lead to additional losses associated with propagation of the electromagnetic wave, e.g., conduction and dielectric losses. The fanning connector configuration can also be associated with a difference in length between bends of conductor strips that comprise a transmission line, resulting in inter-channel skew. Additionally, the bends required in the fan-in leads to intra-channel skew as the length of the two electrodes (PN skew), causing common-mode conversion. Extra transmission line length associated with a fanning connector configuration can lead to additional inter-channel crosstalk as the interaction length increases. These processes can introduce delays between signals traveling in each conduction strip that can be difficult to compensate in small device packages. Furthermore, edge-coupled coplanar lines can be sensitive to the width of the signal conductors and the width of the grounds between two channels.

In contrast, utilizing a connector structure configured to couple a plurality of ECCPS transmission lines with a plurality of BCS transmission lines can be associated with a reduced physical footprint and improved device capabilities. For instance, a connector structure can be configured to have a width similar to a width associated with an integrated circuit device and a width associated with a signal carrying structure. This design can allow for more space to include other electrical, EO, or OE components within a device, which can increase transmission throughput or allow other functionalities to be added. In addition, a high density of components within a device can decrease the complexity of thermal management solutions and any associated power consumption. A ECCPS-BCS connector structure can also comprise shorter conductor line lengths than a ECCPS-ECCPS transition, which can decrease losses associated with conduction and crosstalk. Further, a connector structure can be configured to include conductors with short bends, which can reduce mode conversion and intra-channel skew compared to other configurations. Some conductors can also be configured to have similar lengths, reducing inter-channel skew compared to other configurations. These loss reductions can result in less digital signal processing power being allocated for compensation and towards other application-specific integrated circuit functions.

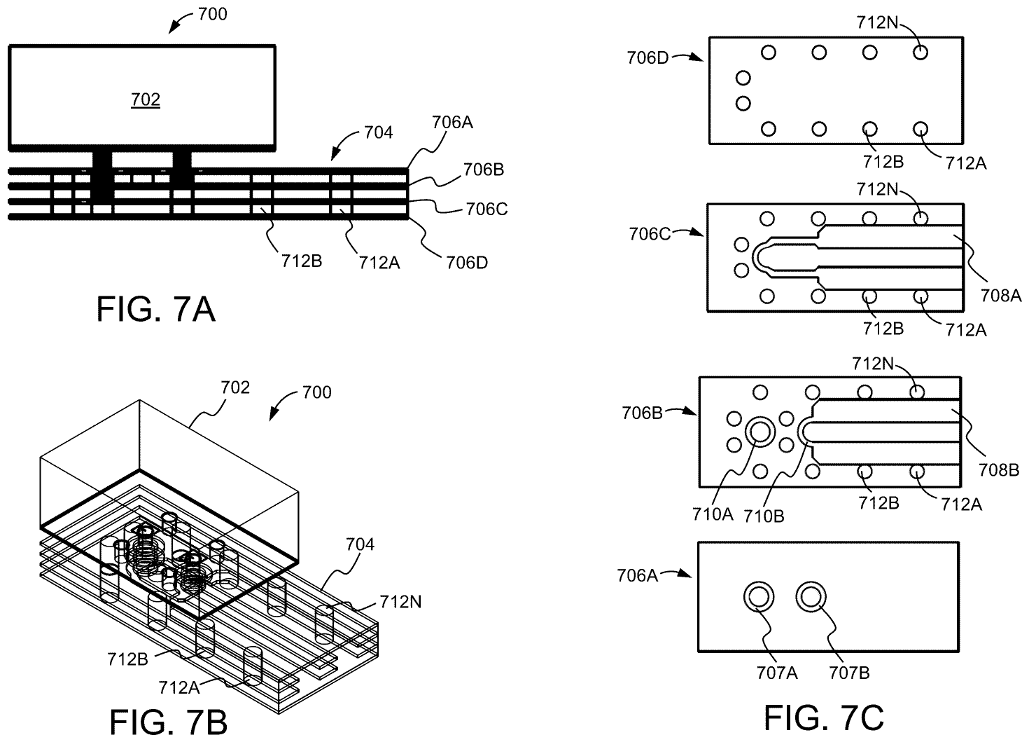

Interfaces can be configured to suppress signal crosstalk between adjacent transmission lines. For example, some connector structures can comprise a first interface that is configured to couple to an integrated circuit device that is also configured to suppress signal crosstalk between conductor strips in a DCTL. In some implementations, the first interface can comprise ground stitching wirebonds from outside grounds associated with the DCTLs. Some connector structures can comprise a second interface that is configured to couple to a signal carrying structure that is also configured to suppress signal crosstalk between conductor strips in a SCSCTL. Some second interfaces configured to suppress crosstalk can comprise ground material between conductor strips. In some implementations, the ground material can have a thickness that is associated with a desired signal impedance and the dimensions of the conductor strips. As described in detail later with respect to FIGS. 7A-7C, some interfaces configured to suppress signal crosstalk between conductor strips in transmission lines can include ground vias.

Balancing signal delays associated with signals propagating through transmission lines configured to carry electromagnetic signals can be a consideration when designing devices. Signal delays can arise from physical properties of materials associated with a device and from differences in the pathlengths of channels in a transmission lines. Some devices can include integrated circuit devices comprising materials associated with one or more dielectric constants and signal carrying structures comprising materials associated with one or more dielectric constants. In some configurations, these materials can be similar to each other such that the associated dielectric constants are equal. Other configurations can include materials that are different from each other such that the associated dielectric constants are not equal. In some devices, the integrated circuit devices and signal carrying structures can be formed from multiple layers of materials wherein each material is associated with a dielectric constant. In these configurations, signals propagating through transmission lines associated with the materials can acquire some delay associated with the different dielectric constants. This propagation delay can be adjusted by reducing or increasing the length and/or width of transmission lines in the connecting structure, the anti-pads, or the transitions in both materials.

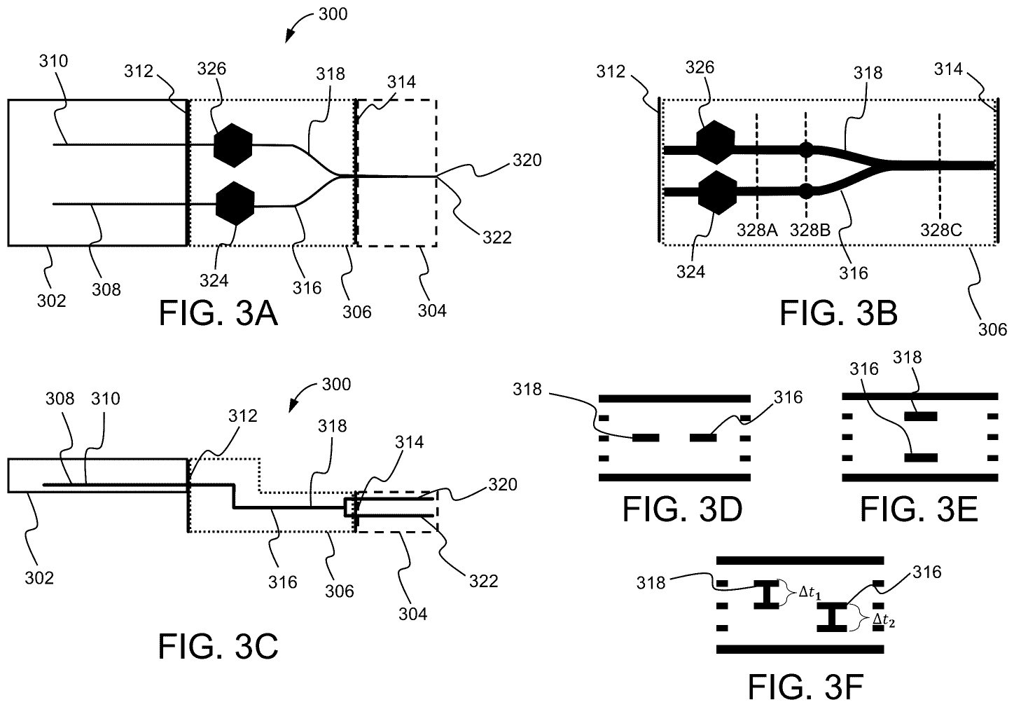

Some connector structures can incorporate conductors designed to compensate for signal delays associated with electromagnetic signals propagating through the transition region. FIG. 3A depicts a top view of an example device 300 comprising an integrated circuit device 302 connected to a signal carrying structure 304 by a connector structure 306. A side view of the example device 300 is depicted in FIG. 3C. The integrated circuit device 302 comprises a conductor strips 308 and 310 arranged in an ECCPS configuration. The signal carrying structure 304 comprises conductor strips 320 and 322 arranged in a BCS configuration. FIG. 3B depicts a top view of the connector structure 306. The connector structure 306 comprises a first interface 312 configured to couple to the integrated circuit device 302 and a second interface 314 configured to couple to the signal carrying structure 304. The connector structure 306 comprises a conductor 316 connecting conductor strip 308 to conductor strip 322 and a conductor 318 connecting conductor strip 310 to conductor strip 320. Between the first interface 312 and the second interface 314, a transition region of connector structure 306 contains coupling locations 324 and 326 to which conductors 316 and 318 are respectively connected. In some implementations, the coupling locations 324, 326 can be contact pads configured to provide electrical connections between two substrates coupled together (e.g., in a flip-chip configuration), where a first substrate includes the conductor strips 308, 310 and the second substrate contains the conductor strips 316, 318. FIG. 3D depicts a two-dimensional perspective view of the transition structure 306 at plane 328A. FIG. 3E depicts a two-dimensional perspective view of the transition structure at plane 328C. FIG. 3F depicts a two-dimensional perspective view of the transition structure at plane 328B. As shown FIGS. 3D-3F, conductors 316 and 318 have geometries to facilitate the transition between conductor strips 308 and 310 having an ECCPS configuration and conductor strips 320 and 322 having a BCS configuration. Conductors 316 and 318 are also configured such that the vertical transitions compensate for any delays Δt₁, Δt₂ associated with signals propagating in the conductors.

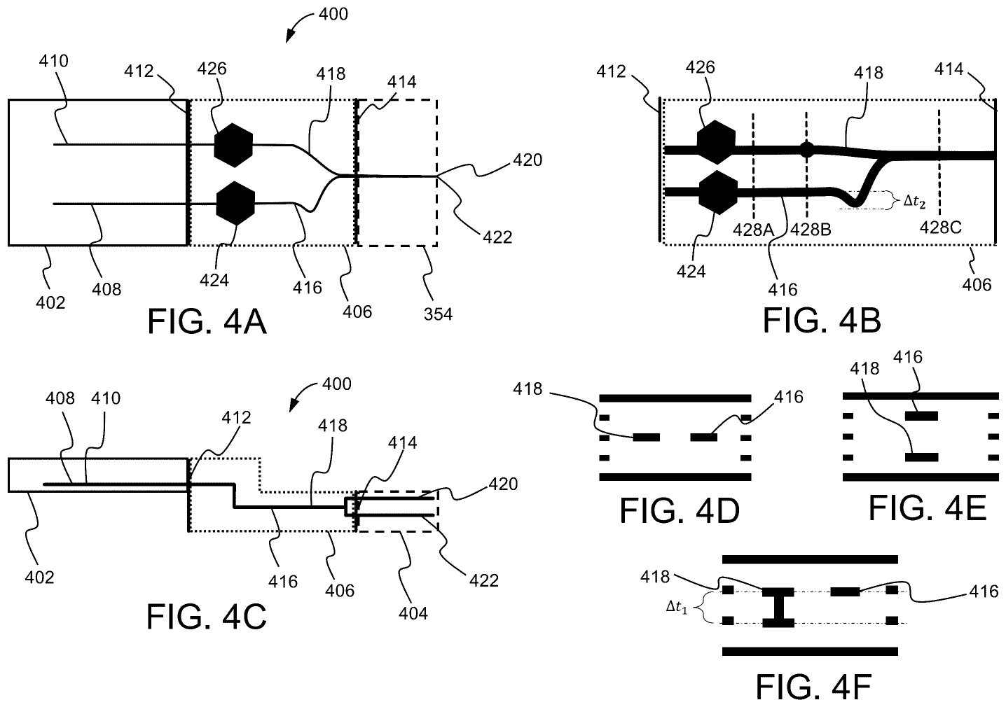

FIG. 4A depicts a top view of an example device 400 comprising an integrated circuit device 402 connected to a signal carrying structure 404 by a connector structure 406. FIG. 4C depicts a side view of the example device 400. The integrated circuit device 402 comprises a conductor strips 408 and 410 arranged in an ECCPS configuration. The signal carrying structure 404 comprises conductor strips 420 and 422 arranged in a BCS configuration. The connector structure 406 comprises a first interface 412 configured to couple to the integrated circuit device 402 and a second interface 414 configured to couple to the signal carrying structure 404. FIG. 4B depicts a top view of the connector structure 406. The connector structure 406 comprises a conductor 416 connecting conductor strip 408 to conductor strip 420 and a conductor 418 connecting conductor strip 420 to 422. Between the first interface 412 and the second interface 414, a transition region of connector structure 406 contains conductor pads 424 and 426 to which conductors 416 and 418 are respectively connected. FIG. 4D depicts a two-dimensional perspective view of the transition structure 406 at plane 428A. FIG. 4E depicts a two-dimensional perspective view of the transition structure at plane 428C. FIG. 4F depicts a two-dimensional perspective view of the transition structure at plane 428B. As shown in FIGS. 4D-4F, conductors 416 and 418 have geometries to facilitate the transition between conductor strips 408 and 410 having an ECCPS configuration and conductor strips 420 and 422 having a BCS configuration. Conductor 416 is configured to have a bend that is associated with a signal delay, Δt₂, to compensate for a signal delay associated with a vertical transition in conductor 418, Δt₁.

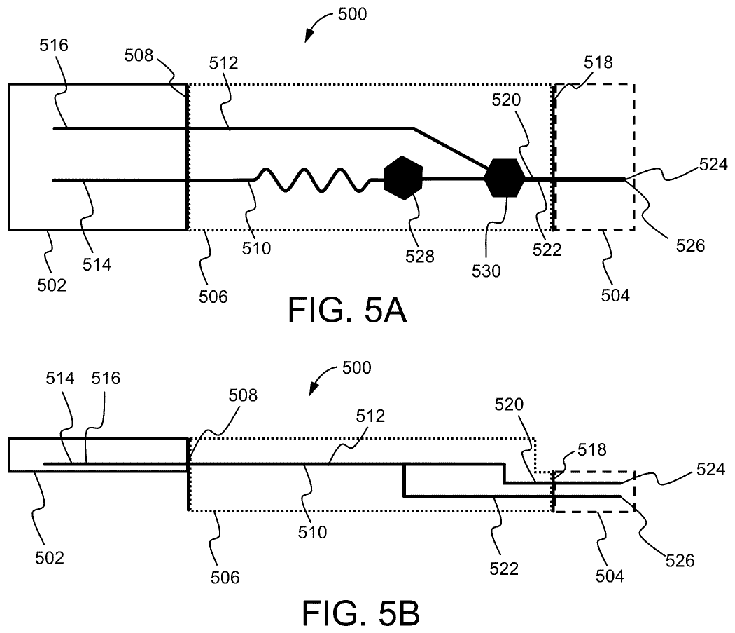

Some connector structures can comprise DCTLs configured to compensate for delays associated with elecromagnetic signals propagating in transmission lines. FIG. 5A depicts a top view and FIG. 5B depicts a side view of an example device 500 comprising an integrated circuit device 502 connected to a signal carrying structure 504 by a connector structure 506. The connector structure 506 has a first interface 508 comprising conductor strips 510 and 512 that are configured to couple to conductor strips 514 and 516 of the integrated circuit device 502. Conductor strips 510, 512, 514, and 516 are substantially coplanar with a first plane. The connector structure 506 has a second interface 518 comprising conductor strips 520 and 522 that are configured to couple to conductor strips 524 and 526 of the signal carrying structure 504. Conductor strips 524 and 526 are distributed along an axis that is substantially perpendicular to the first plane. Between the first interface 508 and the second interface 518, the conductor structure 506 comprises a transition region containing a coupling location 528 that is coplanar with the first plane and a coupling location 530 that is coplanar with the first plane and positioned closer to the second interface 518 than the first coupling location. The conductor strip 522 extends to a first distance from the first plane and connects the coupling location 528 to the conductor strip 526. The conductor strip 520 extends a second distance from the first plane and connects the coupling location 530 to the conductor strip 524. The conductor strip 510 connects the coupling location 528 to the conductor strip 514 while the conductor strip 512 connects the coupling location 530 to the conductor strip 516. The length of the conductor strip 510 is based at least in part on the length of the conductor strip 512 and the difference between a length of the conductor strip 522 and a length of the conductor strip 520.

Some conductor strips can comprise materials such as aluminum, gold, copper, or tungsten. The dimensions of conductor strips can be adjusted depending on available fabrication techniques or signal transmission parameters. Some connector structures can be optimized for a given impedance.

Some integrated circuit devices can be photonic integrated circuit devices or electronic integrated circuit devices. Non-limiting examples of integrated circuit devices include application specific integrated circuits (ASICs) or field-programmable gate arrays (FPGAs). Integrated circuit devices may include or otherwise provide digital signal processors (DSPs), digital-to-analog converters (DACs) and analog-to-digital converters (ADCs), for example.

Some integrated circuit devices can be formed printed circuit boards (PCBs) or substrate like PCBs (SLPs). Some integrated circuit devices can be formed on a flexible PCBs. Some integrated circuit devices can comprise materials such as glass, LTCC, or semiconductor dies.

Some signal carrying structures can be cables configured to carry RF signals between devices. Some signal carrying structures can comprise substrates comprising a host material with embedded transmission lines. Some substrates can be high-density build-up (HDBU) substrates. Some substrates can comprise host materials such as high temperature co-fired ceramic (HTCC) or passivation layers comprising materials such as silicon dioxide, ceramics, organic materials, glass and glass-like materials such as sapphire or diamond, or polymers.

Following a transition structure, some devices can incorporate other components or structures to interface with BCS transmission lines. For instance, some devices can incorporate a chain of multiple components, each comprising transmission lines with a BCS configuration, following a transition structure. This configuration could comprise additional delay lines to compensate any delays associated with the conductor line pitch of the components. This configuration can allow for narrower channel pitch on each component of the chain, thus achieving smaller form factor.

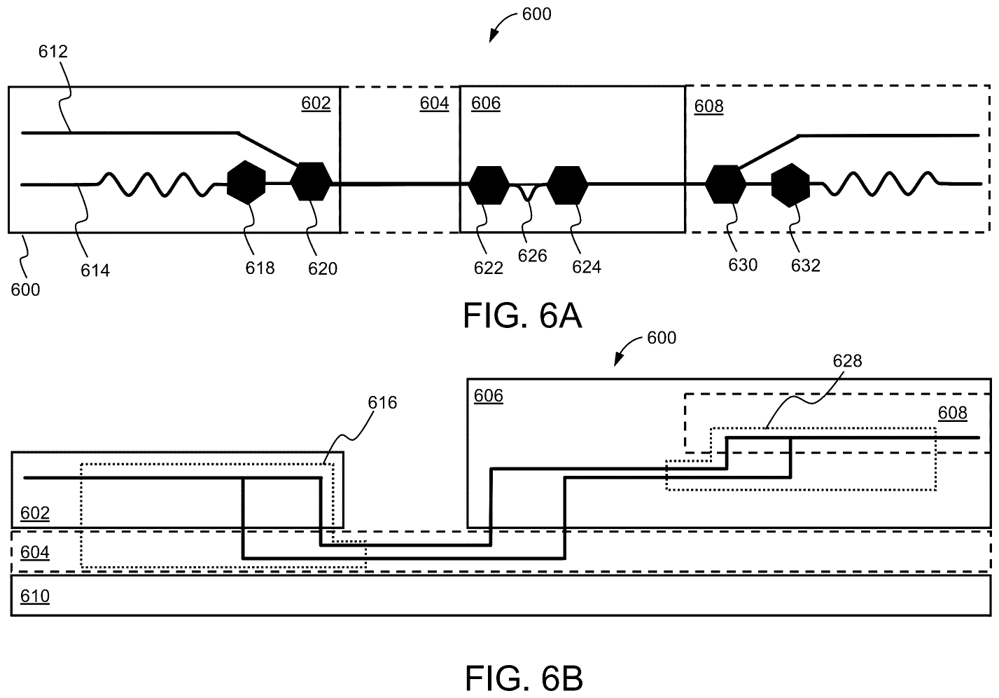

Some devices could also incorporate multiple connector structures to connect transmission lines in several integrated circuit devices and signal carrying structures. FIG. 6A depicts a top view and FIG. 6B depicts a side view of an example device 600 comprising a first integrated circuit device 602, a host material 604, and a package 606 that comprises a second integrated circuit device 608. A carrier 610 serves as the base of the device. Conductor strips 612 and 614 are configured to transmit signals along the length of the device. In the integrated circuit device 602, the conductor strips 612 and 614 are configured in an ECCPS configuration. A connector structure 616 comprising coupling locations 618 and 620 converts the ECCPS configuration to a BCS configuration and the conductor strips 612 and 614 subsequently run through the host material 604. The conductor strips 612 and 614 are coupled to coupling locations 622 and 624 and undergo a vertical transition into package 606. A delay compensation loop 626 can be used to compensate any signal delays associated with this vertical transition. A second transition structure 628 comprising coupling locations 630 and 632 converts the BCS configuration to a ECCPS configuration in the second integrated circuit device 608. The lengths of the conductors 612 and 614 in the transition structures 616 and 628 are configured to compensate for any delays associated with the signals propagating through the device 600.

In some implementations, the use of a connector structure can reduce a signal width, thus increasing conduction losses. To avoid these losses, a connector structure could be implemented at interfaces between components within a device package, as shown in FIG. 6B. Additionally, the package material choice and associated impedance can be limited by the dielectric constant and/or the layer thickness. As the dielectric constant increases for a given impedance, the dielectric layer thickness must increase as well. However, if the layer thickness is too large, unwanted waveguide modes (e.g. TE10) can be excited in a frequency band of interest. The length of the vertical transition can also be important as the delay between the two signals will lead to inductive loading, which might be compensated by the pitch of the vias or their anti-pads.

In some connector structures, the second interface can also comprise a plurality of ground vias, with each ground via extending along an axis that is perpendicular to the first plane. FIG. 7A depicts a side view of an example device 700 comprising an integrated circuit device 702 and a portion of a transition structure 704 that is configured to connect to a signal carrying structure (not shown). The portion of the transition structure 704 comprises layers 706A-706D, where each layer 706A-706D is substantially coplanar to respective plane and each respective plane is parallel with each other plane. Slices of the transition structure 704 along each layer 706A-706D are shown in FIG. 7C. The transition structure 704 comprises a first interface configured to connect to the integrated circuit device 702 and a second interface configured to connect to a signal carrying structure (not shown). A portion of the first interface that extends into the integrated circuit device 702 is not shown. The first interface comprises coupling locations 707A and 707B that are coplanar with the plane that is coplanar with the layer 706A. The second interface comprises conductor strips 708A and 708B that have a BCS configuration. Conductor strips 710A and 710B connect each coupling location 707A and 707B to a respective conductor strip 708A and 708B. The second interface comprises a plurality of ground vias 712A-712N where each ground vias 712A-712N extends along an axis that is perpendicular to the plane that is coplanar with the layer 706A. In some implementations, the density of ground vias can impact crosstalk between conductor strips. Some implementations can comprise ground vias with a pitch<λ/4.

In some implementations, a connector structure can carry a high bandwidth and/or high frequency RF signal chain from a DAC in an electronic integrated circuit (EIC) device to an EIC/driver or photonic integrated circuit. As previously mentioned, utilizing a connector structure can be associated with reduced conduction losses of the high bandwidth RF signal as the signal travels between the EIC and the EIC/driver.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

What is claimed is:

1. An apparatus for carrying electromagnetic signals between an integrated circuit device and a signal carrying structure, the apparatus comprising:
a first interface configured to couple to the integrated circuit device, the first interface comprising
a plurality of device coupling transmission lines DCTLs distributed along a first axis contained within a first plane, each DCTL comprising at least two conductor strips that are distributed along the first axis and are substantially coplanar with the first plane;
a second interface configured to couple to the signal carrying structure, the second interface comprising
a plurality of signal carrying structure coupling transmission line (SCSCTLs) distributed along a second axis, wherein each SCSCTL comprises at least two conductor strips that are distributed along a respective axis that is substantially perpendicular to the second axis; and
a transition region between the first interface and the second interface, the transition region comprising
a transition structure comprising different respective conductors connecting each conductor strip of a DCTL to a respective conductor strip of a corresponding SCSCTL.

2. The apparatus of claim 1, wherein the conductor strips of each SCSCTL are substantially parallel to a second plane that contains the second axis and that is perpendicular to the respective axis along which the conductor strips are distributed.

3. The apparatus of claim 2, wherein at least a portion of each of the conductor strips of a respective SCSCTL at least partially overlaps with a plane that is perpendicular to the second axis.

4. The apparatus of claim 3, wherein the second axis is substantially parallel to the first axis.

5. The apparatus of claim 1, wherein each of the lengths of the two conductor strips in a DCTL are based at least in part on at least one of: (1) the transition structure, or (2) the respective conductor strips of the corresponding SCSCTL.

6. The apparatus of claim 1, wherein the first interface is configured to suppress signal crosstalk between adjacent DCTLs, and the second interface is configured to suppress crosstalk between adjacent SCSCTLs.

7. An apparatus for transmitting electromagnetic signals between an integrated circuit device and a signal carrying structure, the apparatus comprising:
a first interface configured to couple to the integrated circuit device, the first interface comprising
at least one DCTL that comprises first and second conductor strips that are substantially coplanar with a first plane;
a second interface configured to couple to the signal carrying structure, the second interface comprising
at least one SCSCTL that comprises third and fourth conductor strips that are distributed along an axis that is substantially perpendicular to the first plane; and
a transition region between the first interface and the second interface, the transition region comprising
a first coupling location coplanar with the first plane,
a second coupling location coplanar with the first plane and positioned closer to the second interface than the first coupling location,
a first transition structure comprising a first conductor extending to a first distance from the first plane and connecting the first coupling location to the fourth conductor strip, and a second conductor extending to a second distance from the first plane and connecting the second coupling location to the third conductor strip, and
a second transition structure comprising a third conductor coplanar with the first plane and connecting the second coupling location to the first conductor strip, and a fourth conductor coplanar with the first plane and connecting the first coupling location to the second conductor strip;
wherein the third conductor and the fourth conductor are configured to at least partially compensate for a delay associated with electromagnetic signals propagating through one or more of: the first transition structure, the first conductor strip, the second conductor strip, the third conductor strip, or the fourth conductor strip.

8. The apparatus of claim 7, wherein the first interface and the second transition structure comprise a first material having a first dielectric constant, and the second interface and the second transition structure comprise a second material having a second dielectric constant.

9. The apparatus of claim 8, wherein the first dielectric constant and the second dielectric constant are different and the third conductor and the fourth conductor are configured to at least partially compensate for a delay associated with electromagnetic signals propagating through the first material and the second material.

10. The apparatus of claim 7, wherein the delay compensation is based at least in part on (1) a length of the third conductor, and (2) a difference between a length of the first conductor and a length of the second conductor.

11. The apparatus of claim 7, wherein at least a portion of the first conductor extends along an axis that is perpendicular to the first plane.

12. The apparatus of claim 11, wherein the portion of the first conductor that extends along the axis has a length and a thickness that is based at least in part on the length.

13. The apparatus of claim 11, wherein at least a portion of the second conductor extends along an axis that is perpendicular to the first plane.

14. The apparatus of claim 7, wherein the transition structure includes a plurality of ground vias, each ground via in the plurality of ground vias extending along an axis that is perpendicular to the first plane.

15. The apparatus of claim 7, wherein the first coupling location and the second coupling location are distributed along an axis that contains the first conductor strip or the second conductor strip of the at least one DCTL.

16. The apparatus of claim 7, wherein the second interface is configured to suppress signal crosstalk between the third conductor strip and the fourth conductor strip in the SCSCTL.

17. The apparatus of claim 7, wherein the first transition structure comprises one or more layers of a material having a first dielectric constant, where each layer is substantially coplanar with a plane that is parallel to the first plane.

18. An apparatus for carrying electromagnetic signals between an integrated circuit device and a signal carrying structure, the apparatus comprising:
a first interface configured to couple to the integrated circuit device, the first interface comprising
a plurality of edge-coupled coplanar striplines distributed along a first axis, where each edge-coupled coplanar stripline comprises at least two conductor strips;
a second interface configured to couple to the signal carrying structure, the second interface comprising
a plurality of broadside-coupled striplines distributed along a second axis, where each broadside-coupled stripline comprises at least two conductor strips; and
a transition region between the first interface and the second interface, the transition region comprising
a transition structure comprising different respective conductors connecting each conductor strip of an edge-coupled coplanar stripline to a respective conductor strip of a corresponding broadside-coupled stripline.

19. The apparatus of claim 18, wherein the first axis is substantially parallel to the second axis.

20. The apparatus of claim 18, wherein the first interface is configured to suppress signal crosstalk between adjacent edge-coupled coplanar striplines, and the second interface is configured to suppress crosstalk between adjacent broadside-coupled striplines.
